(19) United States
(12) Patent Application Publication
(10) Pub. No.: US 2020/0043951 A1
(43) Pub. Date: Feb. 6, 2020

(54) ELECTRONIC ASSEMBLIES INCORPORATING LAMINATE SUBSTRATES AND METHODS OF FABRICATING THE SAME

(71) Applicant: CORNING INCORPORATED, CORNING, NY (US)

(72) Inventors: GARY STEPHEN CALABRESE, ELMIRA, NY (US); SEAN MATTHEW GARNER, ELMIRA, NY (US); MINGQIAN HE, HORSEHEADS, NY (US); JAMES ROBERT MATTHEWS, PAINTED POST, NY (US)

(21) Appl. No.: 16/485,211

(22) PCT Filed: Feb. 14, 2018
(86) PCT No.: PCT/US2018/018129

§ 371 Date: Aug. 12, 2019

Related U.S. Application Data
(60) Provisional application No. 62/458,785, filed on Feb. 14, 2017.

(51) Int. Cl. H01L 27/12; H01L 51/05; H01L 29/51

(52) U.S. Cl. CPC H01L 27/1218; H01L 29/51; H01L 51/052; H01L 27/1225

(57) ABSTRACT

Electronics assemblies including laminate substrates and methods of manufacture are disclosed. In one embodiment, an electronics assembly (140A) includes a glass-based substrate (110) having a thickness of less than or equal to 300 μm, a first surface (111) and a second surface, at least one gate electrode (155) disposed on the first surface (111) of the glass-based substrate (110), and a polymer layer (154) disposed on the first surface (111) of the glass-based substrate (110). The polymer layer (154) contacts at least a portion of the at least one gate electrode (155). The electronics assembly (140A) further includes at least one source electrode (152), at least one drain electrode (153), and a semiconductor material (151) disposed on the polymer layer (154). The semiconductor material (151) contacts at least a portion of the at least one source electrode (152) and the at least one drain electrode (153). The polymer layer (154) is configured to act as a dielectric material between the at least one gate electrode (155) and the semiconductor material (151).

### BACKGROUND

### Cross-Reference to Related Applications

This application claims the benefit of priority under 35 U.S.C. § 119 of U.S. Provisional Application Ser. No. 62/458785 filed on Feb. 14, 2017 the content of which is relied upon and incorporated herein by reference in its entirety.

### Field

The present specification generally relates to electronics assemblies and, more particularly, to electronics assemblies incorporating laminate substrates comprising polymer and glass-based material layers, and methods of their manufacture.

### Technical Background

Active electronic devices on glass are commonly fabricated using silicon and metal oxide technology, such as is currently practiced in thin-film transistor (TFT) arrays used in liquid crystal and organic light emitting diode (OLED) displays. Current silicon and metal oxide technology requires high deposition temperatures (at least 400° C.) in order to achieve acceptable performance for commercialized display applications. However, low temperature processing alternatives exist in which organic TFTs are utilized rather than silicon or metal oxide. These other materials are processed at significantly lower temperatures than required for silicon or metal oxide, often well below 250° C.

Due to low processing temperatures, large area printed electronics, including roll-to-roll processing, becomes possible as new flexible substrates are a viable option. Many polymers are available in film format on rolls. However, polymer films have drawbacks when used as substrates for electronic devices. Such drawbacks include flatness, barrier properties, surface roughness, and dimensional stability. To make large area format, short pitch, small dimension electronics, such as are needed for high resolution displays, excellent dimensional stability is needed in order to maintain registration between different deposition processing steps, especially in lithographic processes. Polymer films cannot achieve such dimensional stability due to their propensity for plastic deformation under external load and low modulus and resulting stiffness. On the other hand, due to that very plastic nature, polymer films have excellent toughness. Even under stress, in the presence of defects, many polymer films mechanically fail by first irreversible plastic deformation instead of immediate fracture.

Accordingly, there exists a need for alternative thin, flexible substrates for electronic devices that have improved dimensional stability, particularly during device fabrication.

### SUMMARY

In one embodiment, an electronics assembly includes a glass-based substrate having a thickness of less than or equal to 300 μm, a first surface, and a second surface, at least one gate electrode disposed on the first surface of the glass-based substrate, and a polymer layer disposed on the first surface of the glass-based substrate such that the polymer layer contacts at least a portion of the at least one gate electrode. The electronics assembly further includes at least one source electrode disposed on a polymer surface of the polymer layer, at least one drain electrode disposed on the polymer surface, and a semiconductor material disposed on the polymer surface. The semiconductor material contacts at least a portion of the at least one source electrode and the at least one drain electrode. The polymer layer is configured to act as a dielectric material between the at least one gate electrode and the semiconductor material. The at least one gate electrode, a portion of the polymer layer, the at least one source electrode, the at least one drain electrode, and the semiconductor material define at least one electronic device.

In another embodiment, a method of fabricating an electronics assembly including an electronics device includes depositing at least one gate electrode on a first surface of a glass-based substrate, wherein the glass-based substrate has a thickness that is less than or equal to 300 μm, depositing a polymer layer on the first surface of the glass-based substrate such that the polymer layer contacts at least a portion of the at least one gate electrode, wherein the polymer layer comprises a polymer surface, and depositing at least one source electrode and at least one drain electrode on the polymer surface. The method further includes depositing a semiconductor material on the polymer surface such that the semiconductor material contacts at least a portion of the at least one source electrode and at least one drain electrode. The polymer layer is configured to act as a dielectric material between the at least one gate electrode and the semiconductor material. The at least one gate electrode, a portion of the polymer layer, the at least one source electrode, the at least one drain electrode, and the semiconductor material define at least one electronic device.

### BRIEF DESCRIPTION OF THE DRAWINGS

The foregoing will be apparent from the following more particular description of the example embodiments, as illustrated in the accompanying drawings in which like reference characters refer to the same parts throughout the different views. The drawings are not necessarily to scale, emphasis instead being placed upon illustrating the representative embodiments.

FIG. 1A schematically depicts an example laminate substrate comprising a glass-based substrate and a polymer layer according to one or more embodiments described and illustrated herein;

FIG. 1B schematically depicts another example laminate substrate comprising a glass-based substrate and a polymer layer according to one or more embodiments described and illustrated herein;

FIG. 1C schematically depicts another example laminate substrate comprising a polymer layer disposed between a first glass-based substrate and a second glass-based substrate according to one or more embodiments described and illustrated herein;

FIG. 1D schematically depicts another example laminate substrate comprising glass-based substrate disposed between a first polymer layer and a second polymer layer according to one or more embodiments described and illustrated herein;

FIG. 2 schematically depicts a polymer layer being applied to a surface of a glass-glass-based substrate according to one or more embodiments described and illustrated herein;

FIG. 3 schematically depicts an example roll-to-roll process to apply one or more polymer layers to a glass-based substrate according to one or more embodiments described and illustrated herein;

FIG. 4 schematically depicts an example slot-die process to apply one or more polymer layers to a glass-based substrate according to one or more embodiments described and illustrated herein;

FIG. 5 schematically depicts an example lamination process to apply one or more polymer layers to a glass-based substrate according to one or more embodiments described and illustrated herein;

FIGS. 6A-6D schematically depict various thin-film transistor device configurations disposed on the laminate substrates depicted in FIGS. 1A-1D according to one or more embodiments described and illustrated herein;

FIG. 6E schematically depicts a thin-film transistor wherein a polymer layer of the laminate substrate acts as a dielectric layer of the thin-film transistor according to one or more embodiments described and illustrated herein;

FIGS. 7A and 7B schematically depict a process of depositing an array of gate electrodes and a polymer layer on a surface of a glass-based substrate to fabricate an array of electronic devices according to one or more embodiments described and illustrated herein; and

FIGS. 8A and 8B schematically depict electronics assemblies comprising a first electronic device disposed on a first surface of a laminate substrate and a second electronic device disposed on a second surface of the laminate substrate.

### DETAILED DESCRIPTION

The embodiments disclosed herein relate to electronics assemblies incorporating flexible, laminate substrates. Without limitation, the electronics assemblies described herein may be utilized in flexible displays, such as flexible displays incorporating organic thin-film transistors (TFT). Although polymer films are flexible and may thus be used as a substrate for electronic devices such as TFT, polymer films lack dimensional stability. Polymer films also have additional drawbacks, such as flatness, surface roughness, and barrier properties.

Embodiments of the present disclosure address these deficiencies of polymer films by utilizing thin form-factor glass-based substrates. Glass, such as glass sold by Corning Incorporated under the trade name Corning® Willow® glass, may solve the problems that exist with plastic substrates. Flexible glass is available in thin form factor, in both sheet and roll formats. Glass, glass-ceramics, and ceramics (herein referred to collectively as “glass-based substrates”) have excellent transparency, oxygen/water vapor barrier properties, durability, and dimensional stability. Glass-based substrates do not plastically deform under normal handling and moderate temperatures. Under these conditions, dimensional change of glass-based substrates is within the elastic regime. Further, glass-based substrates also do not dimensionally swell due to solvent or moisture absorption. Glass-based substrates may also possess exceptional quality surfaces, due to the fusion forming process. The use of glass-based substrates in such thin form factors may cause issues with respect to mechanical reliability during device fabrication as glass-based substrates may be susceptible to defect induced failures through crack propagation.

As examples, flexible glass-based substrates have advantages over thicker glass in areas of thickness, weight, and flexibility. Glass-based substrates about 300 μm or thinner may be used for flexible/conformable electronics applications and roll-to-roll manufacturing situations that thicker rigid glass is not mechanically compatible with. Thinner glass also has lower optical effects, such as parallax, and UV absorption. Compared to polymer film substrates, flexible glass-based substrates offer improved optical transmission, lower haze, lower surface roughness, higher thermal capability, higher barrier properties, process chemical compatibility, and overall dimensional stability. For example, a thin glass-based substrate as described herein can have an optical transmission of at least about 70%, at least about 80%, or at least about 90%, measured over a wavelength range of 400 nm to 800 nm. Additionally, or alternatively, a thin glass-based substrate as described herein can have a haze of at most about 1%, at most about 0.5%, at most about 0.2%, or at most about 0.1%, measured using a Byk-Gardner Haze-Gard LE04 Haze Meter. Additionally, or alternatively, a thin glass-based substrate as described herein can have a surface roughness of at most about 10 nm, at most about 5 nm, at most about 2 nm, at most about 1 nm, or at most about 0.5 nm, wherein the surface roughness is Ra surface roughness measured over an area of 100 μm×100 μm. Additionally, or alternatively, a thin glass-based substrate as described herein can have a thermal capability of at least about 200° C., at least about 400° C., at least about 500° C., or at least about 700° C. Additionally, or alternatively, a thin glass-based substrate as described herein can have a dimensional stability of at most about 20 μm, at most about 10 μm, or at most about 1 μm, wherein the dimensional stability is the dimensional change or distortion upon heating the glass-based substrate to a processing temperature and then returning it to room temperature. The dimensional stability, specifically, enables high performance devices made of multiple patterned layers that are registered to each other. Free-standing polymer substrates are known to unpredictably distort during processing due to situations of chemical/water absorption, low stiffness resulting in inability to compensate for thin film stresses or applied stress, and stress relaxation due to conditions near Tg. Utilizing a flexible substrate that includes one or more ultra-thin glass-based layers may enable achieving the dimensional stability needed to fabricate high resolution, high registration device structures.

Embodiments described herein combine a thin, glass-based substrate(s) with polymer layer(s) in laminate or coating structures to achieve the favorable properties of both material sets. The excellent dimensional stability and oxygen/water vapor barrier properties of the glass-based substrate may be taken advantage of, while the polymer layer imparts handleability and minimizes contact damage to the surface of the glass-based substrate. Accordingly, embodiments use thin glass-based substrates and polymer layers disposed adjacent to each other as enhanced substrates/superstrates for electronic devices, such as TFT arrays. The laminated structure can be used for sheet-to-sheet and roll-to-roll processes. In most cases, processes will be at low temperature to accommodate organic polymer material thermal properties. However, embodiments of the present disclosure do not exclude the use of these laminate substrates in higher temperature processes if thin glass-based substrate is laminated with high thermal stable polymers, such as, without limitation, polyimides.

The laminate substrates described herein may be utilized in organic TFT backplanes for display devices. Organic TFT structures include organic semiconductor materials, dielectric materials, and TFT designs. Embodiments of the present disclosure are further directed to optimized substrate-device combined structures. In some embodiments, one or more polymer layers disposed on a glass-based substrate may be configured as one or more dielectric layers for electronic devices (e.g., TFT devices) disposed on and/or in the flexible laminate substrate.

Various laminate substrates, electronic assemblies, and methods of fabricating electronics assemblies incorporating laminate substrates are described in detail below.

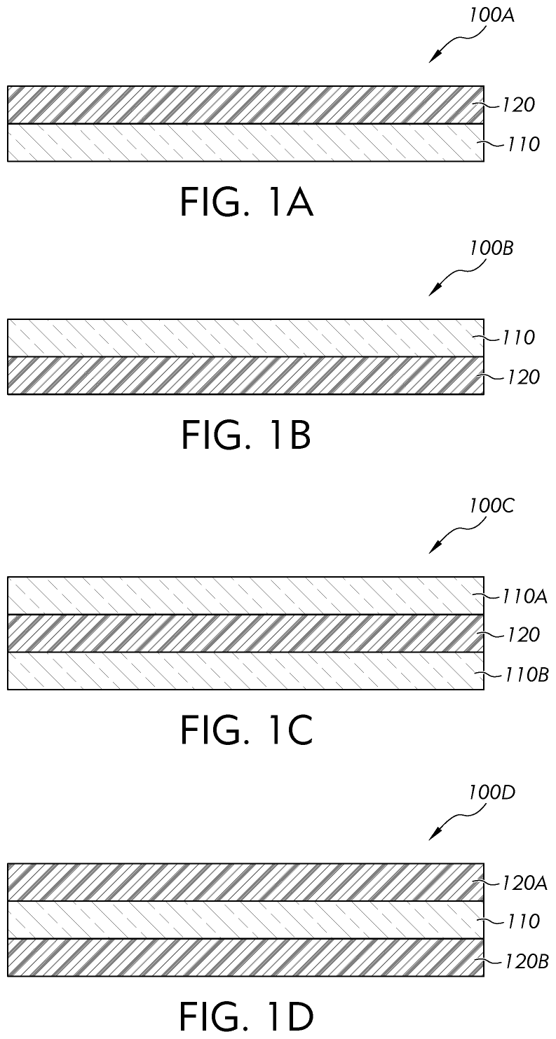

FIGS. 1A-1D schematically illustrate four example glass-polymer substrates (or superstrates) for use in electronics assemblies. Referring to FIG. 1A, an example laminate substrate 100A includes a polymer layer 120 disposed on an upper surface of a glass-based substrate 110. FIG. 1B illustrates an example laminate substrate 100B in which a polymer layer 120 is disposed on a bottom surface of a glass-based substrate 110. FIG. 1C schematically depicts an example laminate substrate 100C in which a polymer layer 120 is sandwiched between a first glass-based substrate 110A and a second glass-based substrate 110B. The glass-based substrates 110A and 110B can either be similar or different. FIG. 1D schematically depicts an example laminate substrate 100D in which a glass-based substrate 110 is sandwiched between a first polymer layer 120A and a second polymer layer 120B. The polymer layers 120A and 120B can either be similar or different. Each of the polymer layer 120 and the glass-based substrate may comprise an individual layer, or be made of multiple layers or composites.

The laminate construction with two glass-based substrates 110A, 110B encompassing a central polymer layer as shown in FIG. 1C has the added advantage of shielding the central polymer layer 120 from oxygen and water. This will extend the operational temperature range of that polymer layer, thus opening up a wider range of processing conditions that this laminate structure will be compatible with.

The glass-based substrates described herein 110 may be made of any glass, glass-ceramic, or ceramic material. As stated above, low temperature processing to fabricate TFT devices (e.g., maximum temperature less than or equal to 300° C.) enables the use of any composition of glass, glass-ceramic, and ceramic materials. Example glass materials include, but are not limited to, borosilicate glass (e.g., glass manufactured by Coming Incorporated of Corning, NY under the trade name Corning® Willow® Glass), alkaline Earth boro-aluminosilicate glass (e.g., glass manufactured by Corning Incorporated under the trade name EAGLE XG®), alkaline earth boro-aluminosilicate glass (e.g., glass manufactured by Corning Incorporated under the trade name Contego Glass), and ion-exchanged alkali-aluminosilicate (e.g., glass manufactured by Corning Incorporated under the trade name Gorilla® Glass). It should be understood that other flexible glass, glass ceramic, ceramic, multi-layers, or composite compositions may also be utilized.

However, high temperature processing of TFT devices (e.g., temperatures greater than 300° C.) may cause migration of alkali ions present within the glass-based substrate 110 into the TFT device, thereby affecting the performance and reliability of the TFT device. Thus, alkali-free glasses can be utilized for the glass-based substrate 110 in high-temperature processing applications where alkali contamination of TFTs is a concern. The presence of alkali ions in the glass-based substrate 110 will not be problematic for low temperature processing because the ions will remain in the glass.

In embodiments, the glass-based substrate 110 has a thickness such that it is flexible. Example thicknesses include, but are not limited to, less than about 300 μm, less than about 250 μm, less than about 200 μm, less than about 150 μm, less than about 100 μm, less than about 50 μm, and less than about 25 μm. For example, the glass-based substrate 110 has a thickness of about 10 μm to about 300 μm. Example glass-based substrates 110 described herein have the ability to bend at a radius of below 300 mm, or a radius below 200 mm, or a radius below 100 mm, or a radius below 75 mm, or a radius below 50 mm, or a radius below 25 mm.

The polymer layer 120 may be any suitably flexible polymer material that is capable of being secured to a surface of the glass-based substrate 110. In an example, the polymer layer 120 covers an entire surface of the glass-based substrate 110. In another example, one or more regions of the surface of the glass-based substrate 110 are not covered by the polymer layer 120. Example polymer materials include, but are not limited to, a polar elastomer, a polyimide, a polycarbonate, a polyvinybutyral, a poly(meth)acryolate. One non limiting example of a polar elastomer includes poly(vinylidene fluoride-co-hexafluoropropylene), as described in more detail below. The polymer layer 120 may be of any suitable thickness, such as, without limitation, within a range of, including endpoints, 0.5 m to 50 μm, or 0.5 μm to 40 μm, or 0.5 μm to 30 μm, or 0.5 μm to 20 μm, or 0.5 μm to 10 μm, or 0.5 μm to 5 μm, or 0.5 μm to 2.5 μm. The polymer layer 120 may have a Young's modulus of less than or equal to 20 GPa, less than or equal to 15 GPa, less than or equal to 10 GPa, or less than or equal to 5 GPa.

The polymer layer 120 may be included in the laminate substrate 100A for its toughness to protect the glass-based substrate 110, particularly during material handling in subsequent processing steps, such as fabrication of TFT devices on the laminate substrate 100A. The polymer layer 120 may minimize contact damage to the surface of the glass-based substrate 110. The polymer layer 120 can be used to accumulate mechanical defects caused by physical contact instead of them being formed in the surface of the glass-based substrate 110. In addition, the polymer layer 120 may act to maintain the integrity of the entire laminate substrate 100A if a mechanical failure occurs in the glass-based substrate 110. Thus, the polymer layer 120 disposed on the glass-based substrate 110 increases the mechanical robustness of the laminate substrate 100A.

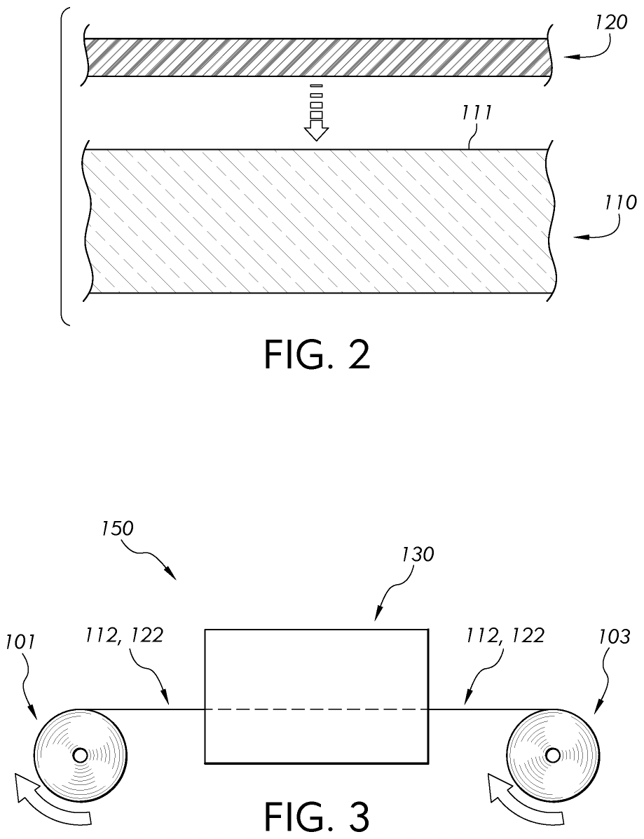

The polymer layer 120 may be applied to the surface(s) of the glass-based substrate 110 by any suitable process. As shown in FIG. 2, a polymer layer 120 configured as a sheet may be disposed on a surface 111 of the glass-based substrate 110 and secured by a lamination process, such as by use of an adhesive material. The adhesive material may be an adhesive film or a liquid based adhesive. In either case, a curing or treatment step may occur after initial lamination, such as, without limitation, a heat-treatment or UV exposure step. With some polymer layer materials, no additional adhesive layer may be needed because the polymer layer 120 may adhere directly to the glass-based substrate 110 without the need for an intermediate material. It should be noted that FIG. 2 depicts a process for adhering free-standing sheets of a polymer layer 120 to the glass-based substrate 110. Alternative processes are also possible that apply a solution-based polymer layer 120 to the glass-based substrate 110 surface followed by any required curing or treatment step, as described in more detail below.

As the glass-based substrate 110 may be a flexible material, the polymer layer 120 may be applied to the glass-based substrate 110 by a roll-to-roll process. Referring now to FIG. 3, a roll-to-roll process 150 for depositing a polymer material 122 onto a glass web 112 is schematically illustrated. It is noted that the polymer material 122 and the glass web 112 form the polymer layer 120 and the glass-based substrate 110, respectively, when cut to size to form the laminate substrate 100A-100D. In the illustrated embodiment, the glass web 112 is in the form of an initial spool 101. The flexible glass web 112 may be wound around a core, for example. The glass web 112 is then unwound toward and through a dielectric layer depositing system 130. The dielectric layer depositing system 130 deposits the polymer material 122 onto one or both surfaces of the glass web 112. After receiving the polymer material 122, the glass web 112 may be wound into a second spool 103 in some embodiments or cut into discrete parts. The coated glass web 112 of the second spool 103 may then be sent to one or more downstream processes, such as, without limitation, via formation (e.g., by laser drilling), electroplating (e.g., to form electrically conductive traces and planes), additional coating, dicing, and electrical component populating. Similarly, the glass web 112 (or glass sheets in a sheet process) may be subjected to one or more upstream processes before depositing a polymer material 122. Similarly, these upstream processes could include, without limitation, via formation (e.g., by laser drilling), electroplating (e.g., to form electrically conductive traces and planes), additional coating, dicing, and electrical component populating. Also, if the polymer material 122 is deposited onto both surfaces of the glass web 112 or glass sheets, it does not need to be symmetric. The polymer material 122 composition, patterning, thicknesses, and other properties on one surface of the glass web 112 or glass sheet can vary from the dielectric material properties on the other surface of the glass web or substrate.

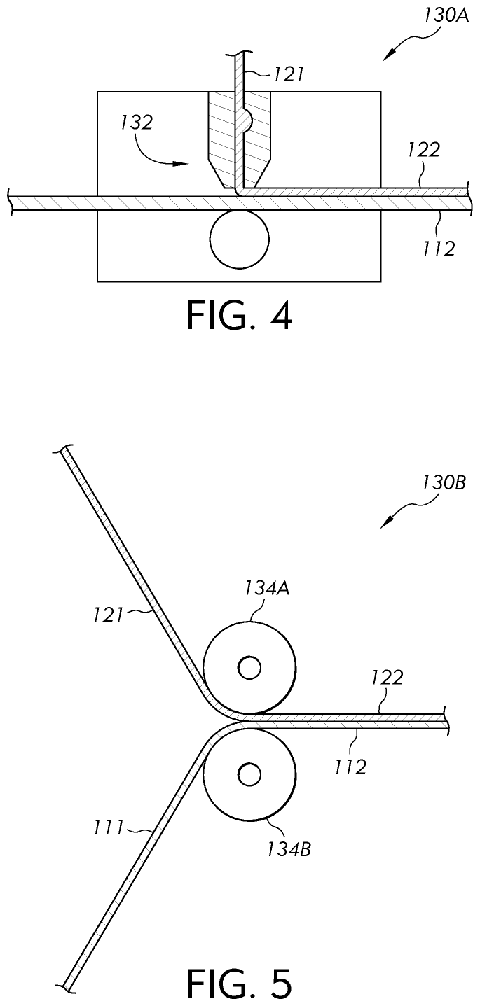

The dielectric layer depositing system 130 may be any assembly or system capable of depositing the polymer material 122 onto the glass web 112. The glass web 112 may be any glass, glass-ceramic, or ceramic material, as described above. As an example and not a limitation, FIG. 4 schematically depicts an example slot-die coating system 130A utilized to deposit a polymer material 122 onto a flexible glass web 112, such as in a roll-to-roll process. It should be understood that the polymer material 122 may be coated onto both surfaces of the glass web 112 (e.g., as shown in FIG. 1D). The slot-die coating system 130A includes a slot-die that continuously deposits the polymer material 122 onto a surface of the glass web 112. It should be understood that, in embodiments wherein both surfaces of the glass web 112 are coated with the polymer material 122, another slot-die may be provided to coat the second surface. Further, additional processing assemblies or systems may also be provided that are not shown in FIG. 4, such as a curing assembly (e.g., thermal curing, UV curing, and the like). It should be understood that coating systems other than slot-die coating may be utilized. Such additional coating systems may include, without limitation, solution-based processes such as printing methods, or other coating methods. The coating system can also include inorganic thin film deposition techniques such as sputtering, plasma-enhanced chemical vapor deposition (PECVD), atomic layer deposition (ALD), and other processes. These methods may be used to deposit continuous layers of polymer material 122 onto the glass web 112.

Referring now to FIG. 5, an example lamination system 130B for applying a polymer material 122 to a flexible glass web 112 is schematically illustrated. The lamination system 130B includes at least two rollers 134A, 134B. The polymer material 122 and the flexible glass web 112 are fed between the rollers 134A, 134B to laminate the polymer material 122 to the flexible glass web 112. In some embodiments, the laminated flexible glass web 112 may then be rolled into a spool. Any known or yet-to-be-developed lamination process may be utilized.

As stated above, the polymer layer 120 may be applied to individual sheets of the glass-based substrate 110 rather than in a roll-to-roll process.

After application of the polymer material 122 to the glass substrate or web 111, the coated glass substrate/web 111 may then be severed into a plurality of laminate substrates having one or more desired shapes.

The laminate substrates described herein (e.g., laminate substrates 100A-100D) may be utilized as a substrate for an electronics assembly. In one non-limiting embodiment, the electronics assembly is an organic TFT backplane used in electronics devices, such as smart phones, for example. It should be understood that embodiments may be incorporated into other electronics assemblies, such as, without limitation, organic light emitting diode displays, organic field-effect transistors, OLED lighting, antennas, touch sensors, circuit board assemblies, photovoltaics, optical and opto-electronic devices, and sensors. Although embodiments are described herein in the context of organic TFT electronics assemblies, it should be understood that embodiments are not limited thereto.

The electronics assemblies described herein may include one or more electronic devices (e.g., TFT electronic device as described below) disposed on and/or in an exposed surface of the laminate substrate. As an example and not a limitation, an array of electronic devices, such as TFT electronic devices, may be disposed on and/or in one or more surfaces of the laminate substrate to provide a TFT backplane for an electronic display.

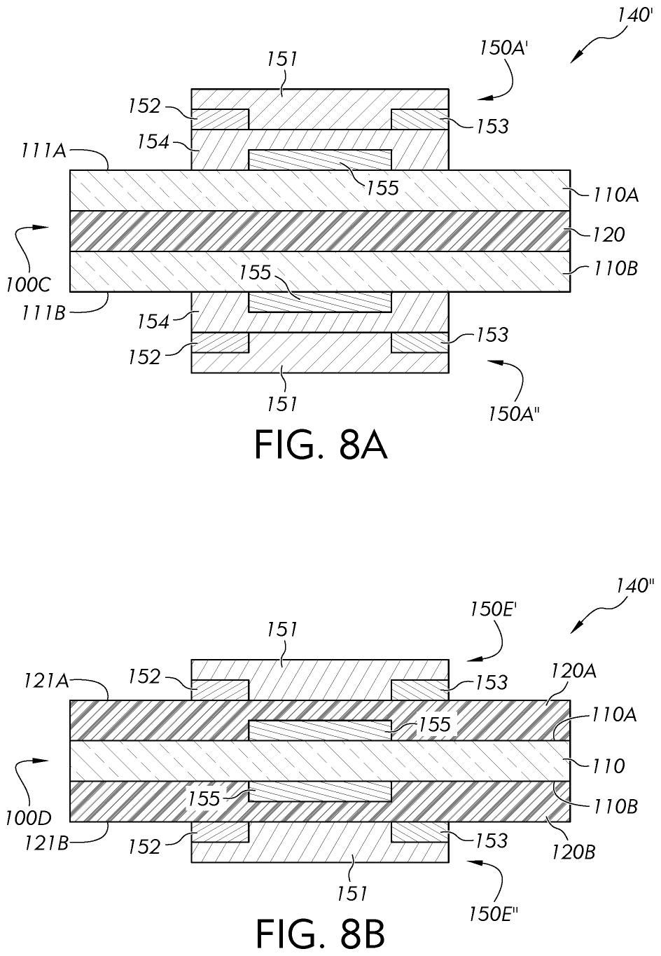

Referring to FIGS. 1A-1D, one or more electronic devices may be disposed on an upper surface of the polymer layers 120, 120A and glass-based substrates 110, 110A. Thus, both the dual- and tri-layer laminate substrates 100A-100D illustrated in FIGS. 1A-1D may be used with the electronic devices placed on either the surface of a glass-based substrate (e.g., glass-based substrate 110 illustrated in FIG. 1B or glass-based-substrate 110A illustrated in FIG. 1C), or the polymer layer (e.g., polymer layer 120 illustrated in FIG. 1A or polymer layer 120A illustrated in FIG. 1D). However, as described below with reference to FIGS. 8A and 8B, electronic devices may be disposed on both exposed sides of a laminate substrate.

It is noted that electronic devices built directly on the surface of the glass-based substrate 110, 110A make use of the excellent surface quality of the glass-based material and make best use of its dimensional stability. However, there may be potential applications in which it may be advantageous to have that high quality surface be presented outwards for interaction with the outside environment. In such cases, it would be viable to build the electronic devices (e.g., TFT arrays) on the surface of the polymer layer 120, 120A. There are also situations in which the polymer layer might impart other useful functionality of its own in terms of materials properties for outside interaction. In such cases, the laminate substrates 100B and 100D illustrated in FIGS. 1B and 1D may be useful. It is noted that where high quality surfaces are desired for both device construction and for outside interfacing, the laminate substrate 100C illustrated in FIG. 1C would likely be most appropriate.

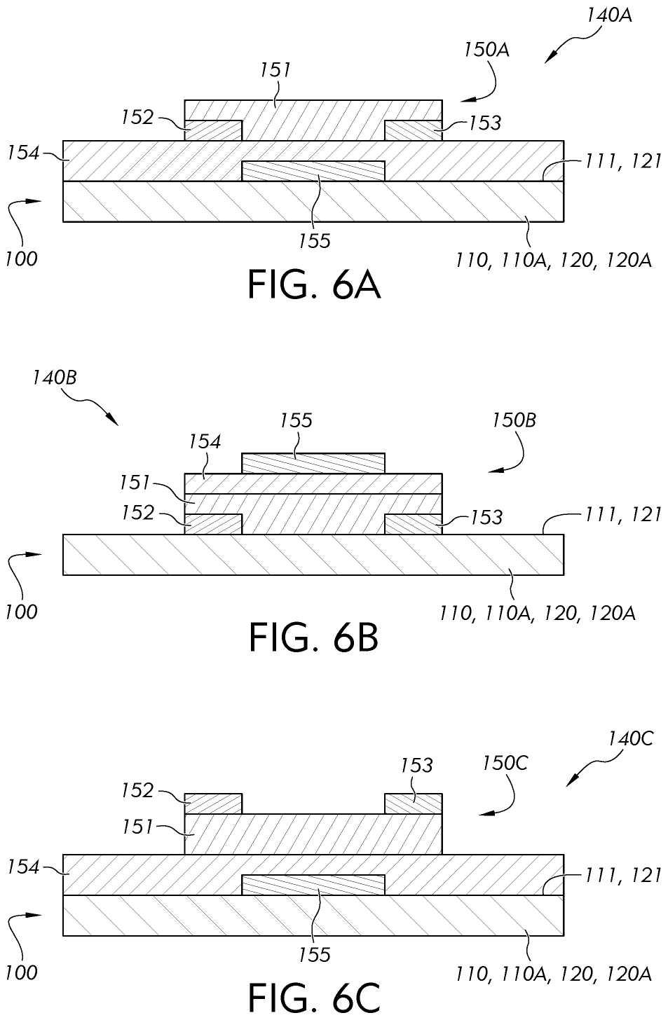

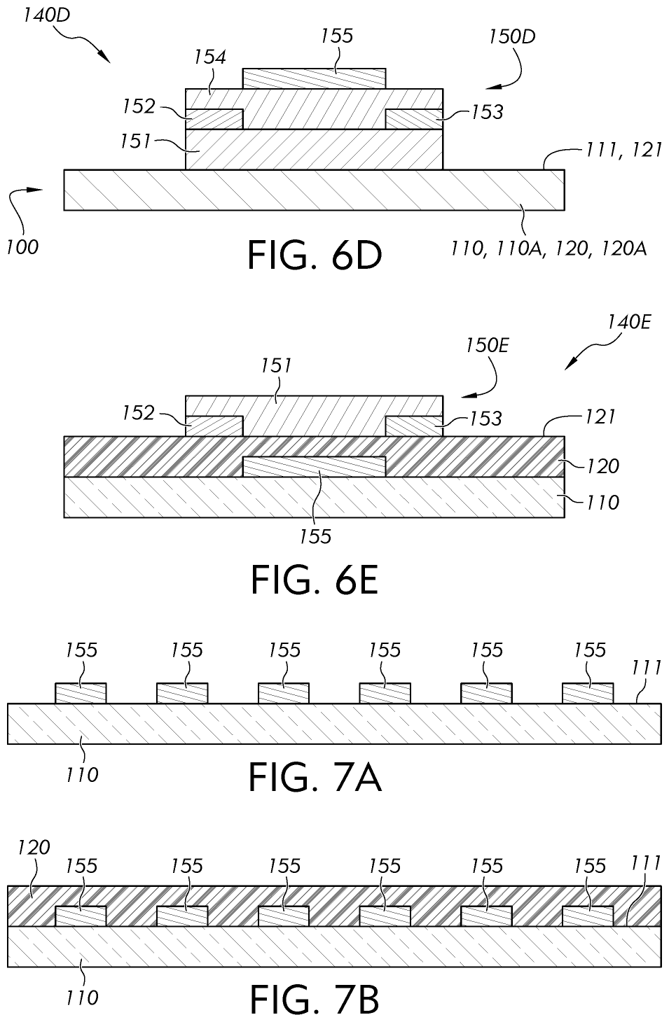

There are a number of various possible TFT configurations for the electronic devices that may be built on the laminate substrates 100A-100D illustrated in FIGS. 1A-1D. In the non-limiting examples illustrated by FIGS. 6A-6D, the electronic devices are built on the surface of either a glass-based substrate 110, 110A or a polymer layer 120, 120A. It should be understood that the individual layers of the laminate substrate 100 are not illustrated in FIGS. 6A-6D for ease of illustration.

FIG. 6A schematically depicts an electronics assembly 140A having an electronic device 150A disposed on a surface 111, 121 of a laminate substrate 100. The example electronic device 150A is configured as a bottom gate/bottom contact TFT device, such as an organic TFT device, for example. In the illustrated embodiment, a gate electrode 155 is disposed on a surface 111, 121 of the glass-based substrate 110 or the polymer layer 120. For all of the embodiments disclosed herein, the gate electrode 155 may be fabricated from any suitable electrically conductive material. In display applications, a transparent electrically conductive material such as, without limitation, indium tin oxide (ITO) may be utilized for the gate electrode. Other materials for the gate electrode 155 (as well as the source electrode 152 and the drain electrode 153 described below) include, but are not limited to, fluorinated tin oxide, carbon nanotube networks, silver nanowire networks, metals such as, gold, silver, copper, aluminum, molybdenum, and alloys thereof

The electronic device 150A further includes a dielectric layer 154 deposited or otherwise disposed on the surface 111, 121 of the glass-based substrate 110 or the polymer layer 120 such that it contacts at least a portion of the gate electrode 155. The dielectric layer 154 is chosen such that the gate is insulated from a source electrode 152, a drain electrode 153, and a semiconductor material 151. Example materials for the dielectric layer include, but are not limited to, non-conductive polymers, such as, fluoro-elastomers, polystyrene, polyvinylphenol, polymethylmethacrylate and polyimides.

An electrically conductive source electrode 152 and an electrically conductive drain electrode 153 are deposited or otherwise disposed on a surface of the dielectric layer 154. The source electrode 152 and the drain electrode 153 may be fabricated from the same electrically conductive materials as the gate electrode 155 (e.g., ITO), and the various electrodes of the electronic device 150A can be fabricated from the same or different materials. The electronic device 150A further includes a semiconductor material 151 deposited or otherwise disposed on a surface of the dielectric layer 154 such that the semiconductor material 151 contacts at least a portion of the source electrode 152 and the drain electrode 153. Example semiconductor materials include, but are not limited to, small molecule organic semi-conductors, polymeric organic semi-conductors, including fused thiophene and/or diketopyrrolopyrrole containing conjugated polymers and metal oxide semi-conductors. The various components of any of the electronic device described herein may be fabricated using any known or yet-to-be-developed TFT fabrication techniques.

FIG. 6B schematically depicts an electronics assembly 140B having an electronic device 150B disposed on a surface 111, 121 of a laminate substrate 100. The example electronic device 150B is configured as a top gate/bottom contact TFT device, such as an organic TFT device, for example. In the illustrated embodiment, a source electrode 152, a drain electrode 153, and a semiconductor material 151 are deposited or otherwise disposed on a surface 111, 121 of the laminate substrate 100 such that the semiconductor material 151 contacts at least a portion of the source electrode 152 and the drain electrode 153. In the illustrated embodiment, a dielectric layer 154 is disposed on a surface of the semiconductor material 151, and an electrically conductive gate electrode 155 is disposed on a surface of the dielectric layer 154. The components of the example electronic device 150B may be fabricated from any of the materials provided above with respect to the example electronic device 150A depicted in FIG. 6A.

FIG. 6C schematically depicts an electronics assembly 140C having an electronic device 150C disposed on a surface 111, 121 of a laminate substrate 100. The example electronic device 150C is configured as a bottom gate/top contact TFT device, such as an organic TFT device, for example. In the illustrated embodiment, a gate electrode 155 and a dielectric layer 154 are deposited or otherwise disposed on a surface 111, 121 of the laminate substrate 100 such that the dielectric layer 154 contacts at least a portion of the gate electrode 155. A semiconductor material 151 is deposited or otherwise disposed on a surface of the dielectric layer 154. A source electrode 152 and a drain electrode 153 are deposited or otherwise disposed on a surface of the semiconductor material 151. The components of the example electronic device 150C may be fabricated from any of the materials provided above with respect to the example electronic device 150A depicted in FIG. 6A.

FIG. 6D schematically depicts an electronics assembly 140D having an electronic device 150D disposed on a surface 111, 121 of a laminate substrate 100. The example electronic device 150D is configured as a top gate/top contact TFT device, such as an organic TFT device, for example. In the illustrated embodiment, a semiconductor material 151 is deposited or otherwise disposed on a surface 111, 121 of the laminate substrate 100. A source electrode 152, a drain electrode 153, and a dielectric layer 154 are deposited or otherwise disposed on a surface of the semiconductor material 151 such that the dielectric layer 154 contacts at least a portion of the source electrode 152 and the drain electrode 153. A gate electrode 155 is deposited or otherwise disposed on a surface of the dielectric layer 154. The components of the example electronic device 150D may be fabricated from any of the materials provided above with respect to the example electronic device 150A depicted in FIG. 6A.

An array of electronic devices (e.g., electronic devices 150A-150D depicted in FIGS. 6A-6D) may be provided on a surface 111, 121 of the laminate substrate 100. The flexibility of the glass-based substrate(s) and the polymer layer(s) of the laminate substrate 100 may enable a flexible electronic display, such as an organic TFT display, for example. In embodiments, the resulting electronic assembly 140 is flexible such that it is capable of achieving a bend radius of 300 mm or smaller.

The example TFT electronic devices 150A and 150D depicted in FIGS. 6A and 6D, respectively, each have bottom gates, and enable the possibility of an advanced structure that utilizes the polymer layer 120 of the laminate substrate 100 also functioning as a dielectric layer (e.g., the dielectric layer 154 depicted in FIGS. 6A and 6D). The polymer material of the polymer layer 120, 120A, 120B may be chosen such that it may function as a thicker dielectric layer (e.g., micron scale) than a dielectric layer of a traditional TFT device (e.g., tens of nanometers scale) without compromising operational voltage or performance. Thus, the polymer layer 120 may be utilized as a structural component as described above (i.e., to prevent damage to the glass-based substrate 110) as well as an electronic component (i.e., to serve as a dielectric layer). Example polymer materials that may serve as both a structural component and an electronic component as a dielectric material include, but are not limited to, poly(vinylidene fluoride-co-hexafluoropropylene) (“e-PVDF-HFP”), polyimides, epoxy polymers and (meth)acrylate polymers. A non-limiting example of polymer layer 120 material is an e-PVDF-HFP layer having a thickness of less than 5 μm, for example, without limitation, 1 μm to 5 μm.

Referring now to FIG. 6E, an electronics assembly 140E including an electronic device 150E utilizing a polymer layer 120 as a dielectric layer is schematically depicted. The example electronic device 150E is configured as a bottom gate/bottom contact TFT device as described above in reference to FIG. 6A. However, unlike the example illustrated in FIG. 6A, the electronic device 150E utilizes the polymer layer 120 as a dielectric layer. Because glass is available in a thin form factor in rolls, and is handleable without the polymer layer 120 present, deposition of electrodes may be made directly onto the surface of the glass-based substrate 110. One non-limiting example of a rolled glass-based substrate 110 is glass manufactured by Corning Incorporated of Corning, NY under the trade name Corning® Willow® Glass.

As shown in FIG. 7A, an array of gate electrodes 155 may be deposited onto a surface 111 of the glass-based substrate 110 in roll-to-roll processing, or on individual sheets of the glass-based substrate 110. Next, as shown in FIG. 7B, a polymer layer 120 may be deposited or otherwise disposed on the surface 111 of the glass-based substrate 110 in roll-to-roll processing, or on individual sheets of the glass-based substrate 110. The polymer layer 120 contacts the gate electrodes 155 and the glass-based substrate 110 such that the polymer layer 120 acts as both an electronic component and a structural component. For example, the polymer layer 120 can protect the surface of the glass-based substrate 110 to provide increased toughness while also acting as the dielectric layer of the electronic device. It is noted that the polymer layer does not need to have a substantially equal thickness across the entire laminate substrate 100. For example, the thickness of the polymer layer 120 may vary substantially (>0.01 μm, >0.05 μm, >0.1 μm, >0.5 μm, >1 μm, >5 μm) over the laminate substrate 100. Intentional variation in thickness can be achieved by subtractive methods (e.g., etching) or additive (e.g., printing). It may be desired to produce this locally optimized variation in thickness so that the polymer layer 120 is thicker in regions requiring more mechanical performance and thinner in regions as required for electrical performance. For example, the polymer layer 120 is thinner in regions disposed on the gate electrodes 155 and thicker in regions disposed on the glass-based substrate 110 (e.g., between adjacent gate electrodes) as illustrated in FIG. 7B.

Referring once again to FIG. 6E, a source electrode 152, a drain electrode 153, and a semiconductor material 151 are deposited or otherwise disposed on the surface 121 of the polymer layer 120. Accordingly, the gate electrode 155, the polymer layer 120, the source electrode 152, the drain electrode 153, and the semiconductor material 151 define an electronic device 150E, such as a TFT device. It should be understood that an array of electronic devices 150E may be provided on a laminate substrate 100.

In some embodiments, the glass-based substrate 110 and the polymer layer 120 can be separated or debonded from each other. For example, the polymer layer 120 can be separated from the glass-based substrate 110 after deposition of the gate electrode 155, the polymer layer 120, the source electrode 152, the drain electrode 153, and/or the semiconductor material 151 as described herein. In some of such embodiments, the glass-based substrate 110 can serve as a carrier for forming the electronic device, and the electronic device can be removed from the carrier following processing. Additionally, or alternatively, the polymer layer 120 can protect the glass-based substrate 110 during the various processing steps as described herein.

Electronic assemblies with electronic devices disposed on both sides of a laminate substrate are also possible. In such embodiments, the laminate substrate may serve as an intra-state. These electronic devices on both sides of the substrate can be registered to each other (e.g., within ±10 μm, within ±5 μm, or within ±1 μm) or non-aligned. The electronic devices can also include categories of opto-electronic and optical devices. The electronic devices can also interact with each other electrically, optically, or through other methods. This interaction could make use of via holes in the substrate or the substrate's transparency. Referring now to FIG. 8A, an example electronics assembly 140′ is schematically illustrated. The example electronics assembly 140′ comprises a laminate substrate 100C, a first electronic device 150A′, and a second electronic device 150A″. The laminate substrate 100C comprises a polymer layer 120 disposed between a first glass-based substrate 110A and a second glass-based substrate 110B. The first electronic device 150A′, which may be a TFT device, is disposed on a first surface 111A of the first glass-based substrate 110. The second electronic device 150A″ which may also be a TFT device, is disposed on a second surface 111B of the second glass-based substrate 110. Each of the first electronic device 150A′ and the second electronic device 150A″ includes a gate electrode 155 and a dielectric layer 154 deposited or otherwise disposed on the first surface 111A of the first glass-based substrate 110A and the second surface 111B of the second glass-based substrate 110B, respectively. Each of the first electronic device 150A′ and the second electronic device 150A″ includes a source electrode 152, a drain electrode 153, and a semiconductor material 151 deposited or otherwise disposed on the respective dielectric layers 154. It should be understood that an array of first electronic devices 150A′ and second electronic devices 150A″ may be disposed on the first surface 111A of the first glass-based substrate 110A and the second surface 111B of the second glass-based substrate 110B, respectively.

FIG. 8B depicts another example electronics assembly 140″ having electronic devices disposed on both sides of a laminate substrate 100D. The laminate substrate 100D comprises a glass-based substrate 110 disposed between a first polymer layer 120A and a second polymer layer 120B. In the example electronics assembly 140″ illustrated in FIG. 8B, the first polymer layer 120A and the second polymer layer 120B act as dielectric layers for a first electronic device 150E′ and a second electronic device 150E″, respectively, in a manner similar as described above with respect to FIG. 6E. A gate electrode 155 and the first polymer layer 120A are deposited or otherwise disposed on the first surface 111A of the glass-based substrate 110. A source electrode 152, a drain electrode 153, and a semiconductor material 151 are deposited or otherwise disposed on a surface 121A of the first polymer layer 120A. Similarly, a gate electrode 155 and the second polymer layer 120B are deposited or otherwise disposed on the second surface 111B of the glass-based substrate 110. A source electrode 152, a drain electrode 153, and a semiconductor material 151 are deposited or otherwise disposed on a surface 121B of the second polymer layer 120B. It should be understood that an array of first electronic devices 150E′ and second electronic devices 150E″ may be disposed on the first surface 111A of the glass-based substrate 110 and the second surface 111B of the glass-based substrate 110, respectively.

While exemplary embodiments have been described herein, it will be understood by those skilled in the art that various changes in form and details may be made therein without departing from the scope encompassed by the appended claims.

1. An electronics assembly comprising:
a glass-based substrate having a thickness of less than or equal to 300 μm, the glass-based substrate comprising a first surface and a second surface;
at least one gate electrode disposed on the first surface of the glass-based substrate;
a polymer layer disposed on the first surface of the glass-based substrate such that the polymer layer contacts at least a portion of the at least one gate electrode, wherein the polymer layer comprises a polymer surface;
a semiconductor material disposed on the polymer surface;
at least one source electrode; and
at least one drain electrode, wherein:
the polymer layer is configured to act as a dielectric material between the at least one gate electrode and the semiconductor material; and
the at least one gate electrode, a portion of the polymer layer, the at least one source electrode, the at least one drain electrode, and the semiconductor material define at least one electronic device.

2. The electronics assembly of claim 1, wherein the polymer layer is selected from a group consisting of: a polar elastomer, a polyimide, a polycarbonate, a polyvinybutyral, a poly(meth)acryolate, and combinations thereof.

3. The electronics assembly of claim 2, wherein the polymer layer has a thickness within a range of about 0.5 μm to about 50 μm.

4. The electronics assembly of claim 2, wherein the polymer layer has a Young's modulus of less than or equal to 10 GPa.

5. The electronics assembly of claim 1, wherein the polymer layer is poly(vinylidene fluoride-co-hexafluoropropylene).

6. The electronics assembly of claim 5, wherein the polymer layer has a thickness that is less than or equal to 5 μm.

7. The electronics assembly of claim 1, wherein the glass-based substrate comprises an alkali glass.

8. The electronics assembly of claim 1, wherein the glass-based substrate is ion-exchanged.

9. The electronics assembly of claim 1, wherein the glass-based substrate comprises an alkali-free glass.

10. The electronics assembly of claim 1, wherein the electronics assembly has a bend radius of less than or equal to 300 mm.

11. (canceled)

12. The electronics assembly of claim 1, further comprising
at least one additional gate electrode disposed on the second surface of the glass-based substrate;
an additional polymer layer disposed on the second surface of the glass-based substrate such that the additional polymer layer contacts at least a portion of the at least one additional gate electrode, wherein the additional polymer layer comprises an additional polymer surface;
an additional semiconductor material disposed on the additional polymer surface;
at least one additional source electrode; and
at least one additional drain electrode, wherein:
the additional polymer layer is configured to act as a dielectric material between the at least one additional gate electrode and the additional semiconductor material; and
the at least one additional gate electrode, a portion of the additional polymer layer, the at least one additional source electrode, the at least one additional drain electrode, and the additional semiconductor material define at least one additional electronic device.

13. The electronics assembly of claim 1, wherein:
the at least one source electrode is disposed on the polymer surface;
the at least one drain electrode is disposed on the polymer surface; and
the semiconductor material contacts at least a portion of the at least one source electrode and at least a portion of the at least one drain electrode.

14. The electronics assembly of claim 1, wherein the at least one source electrode and the at least one drain electrode are disposed on a surface of the semiconductor material.

15. A method of fabricating an electronics assembly comprising an electronics device, the method comprising:
depositing at least one gate electrode on a first surface of a glass-based substrate, wherein the glass-based substrate has a thickness that is less than or equal to 300 μm;
depositing a polymer layer on the first surface of the glass-based substrate such that the polymer layer contacts at least a portion of the at least one gate electrode, wherein the polymer layer comprises a polymer surface;
depositing at least one source electrode and at least one drain electrode on the polymer surface; and
depositing a semiconductor material on the polymer surface such that the semiconductor material contacts at least a portion of the at least one source electrode and at least a portion of at least one drain electrode, wherein:
the polymer layer is configured to act as a dielectric material between the at least one gate electrode and the semiconductor material; and
the at least one gate electrode, a portion of the polymer layer, the at least one source electrode, the at least one drain electrode, and the semiconductor material define at least one electronic device.

16. A method of fabricating an electronics assembly comprising an electronics device, the method comprising:
depositing at least one gate electrode on a first surface of a glass-based substrate, wherein the glass-based substrate has a thickness that is less than or equal to 300 μm;
depositing a polymer layer on the first surface of the glass-based substrate such that the polymer layer contacts at least a portion of the at least one gate electrode, wherein the polymer layer comprises a polymer surface;
depositing a semiconductor material on the polymer surface; and
depositing at least one source electrode and at least one drain electrode on a surface of the semiconductor material, wherein:
the polymer layer is configured to act as a dielectric material between the at least one gate electrode and the semiconductor material; and
the at least one gate electrode, a portion of the polymer layer, the at least one source electrode, the at least one drain electrode, and the semiconductor material define at least one electronic device.

17-20. (canceled)

21. The method of claim 15, wherein the polymer layer is deposited onto the first surface of the glass-based substrate by slot-die coating.

22. The method of claim 15, wherein the electronics assembly is fabricated at a maximum temperature that is less than or equal to 300° C.

23-27. (canceled)

28. The method of claim 15, wherein the electronics assembly is fabricated by roll-to-roll processing.

29. The method of claim 16, wherein the polymer layer is deposited onto the first surface of the glass-based substrate by slot-die coating.

30. The method of claim 16, wherein the electronics assembly is fabricated at a maximum temperature that is less than or equal to 300° C.

31. The method of claim 16, wherein the electronics assembly is fabricated by roll-to-roll processing.
